(19) United States
(12) Patent Application Publication
(10) Pub. No.: US 2010/0134198 A1
(43) Pub. Date: Jun. 3, 2010

(54) METHOD FOR THE PRODUCTION OF A DIGITALLY MODULATED HIGH-FREQUENCY SIGNAL

(76) Inventors: Nikolaus Demharter, Dormitz (DE); Philipp Höcht, Lauf (DE)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/530,812

(22) PCT Filed: Mar. 14, 2008
(86) PCT No.: PCT/EP2008/053055

§ 371 Date: Sep. 11, 2009

(30) Foreign Application Priority Data
Mar. 20, 2007 (DE) 10 2007 013 423.3

(51) Int. Cl. H03C 1/00

(52) U.S. Cl. 332/149

(57) ABSTRACT

In a method for the production of a radio-frequency signal modulated as a function of a low-frequency digital data stream, a clock signal is provided having a frequency that is at least four times as high as the frequency of the radio-frequency signal to be produced. The clock signal is used for mixing the low-frequency data stream with a cyclical numeric sequence representing a continuous sinusoidal or co-sinusoidal series. A circuit arrangement implements such a method to produce a radio-frequency signal modulated as a function of a low-frequency digital data stream, and a magnetic resonance tomography system employs such a circuit arrangement.

### BACKGROUND OF THE INVENTION

### 1. Field of the Invention

The invention concerns a method to generate a radio-frequency signal modulated depending on a low-frequency digital data stream. Furthermore, the invention concerns a circuit arrangement in which a radio-frequency signal modulated depending on a low-frequency digital data stream can be generated with such a method. Moreover, the invention concerns a magnetic resonance tomography system with such a circuit arrangement.

2. Description of the Prior Art

In a number of technical systems, radio-frequency signals modulated in a specific way are required. Typical application examples are found in, among other things, message transmission technology and medical technology. For example, modulated radio-frequency signals are required within magnetic resonance systems in the medical technology field. In order to generate an image with the aid of a magnetic resonance tomography method, defined radio-frequency pulses must be radiated into the body or the body part of the patient that is to be examined, the patient being located in a precisely defined magnetic field. The nuclear spins of the atoms in the examination subject are thereby excited. The signals of the nuclear spins that are emitted as a result are detected and acquired as raw data from which the desired magnetic resonance images can be generated. It is necessary that the individual radio-frequency pulses have a precisely specified frequency that corresponds to the resonance frequency of the atoms to be excited in the present magnetic field. In a magnetic field of 3 Tesla, this resonance frequency to excite the (typically excited) H₁ atoms is 123 MHz. A variety of known sequences of radio-frequency pulses are available, and different sequences are used for different examinations, and every single radio-frequency pulse should have a precisely defined temporal length, amplitude and shape in order to achieve a specific effect. The parameters necessary for this are typically provided in the form of a digital data stream which is mixed with a mixing frequency MF so that the modulated radio-frequency signal (for example the required series of necessary radio-frequency pulses) results overall.

A typical scheme for such a digital modulation is presented in FIG. 1. A mixing frequency MF that is freely selectable in stages (i.e. an unmodulated radio-frequency signal with the desired mixing frequency) is generated in an NCO (Numerical Controlled Oscillator) on the basis of a reference signal RS (for example a system clock) which can also serve for synchronization with other units of the complete system. Given use in a magnetic resonance system, for example, thus can be the cited resonance frequency of 123 MHz. Within the NCO, the mixing frequency MF is generated by means of a phase accumulator and a subsequent conversion of the phase into sine and/or cosine vectors. Such NCOs are generally known and therefore do not need to be explained in detail herein. The mixing frequency MF is then supplied to a digital mixing stage MS in order to mix it with the low-frequency data stream NF which ultimately provides the pulse shape of the desired radio-frequency signal RF. The “mixed” radio-frequency signal modulated in the desired manner on the basis of the digital low-frequency input signal NF is therefore present at the output, which modulated radio-frequency signal can be supplied (possibly filtered) to a digital-analog converter for conversion into an analog signal. The typical registers used before and after the mixing stage MS, which are likewise synchronized by the reference signal RS, are also shown in FIG. 1. These merely serve to reduce the length of the entire logic path and thus to achieve an optimally quick logic in a known manner.

However, the typical scheme shown in FIG. 1 has disadvantages. Digital multipliers are required for the mixing of the low-frequency data stream NF with the mixing frequency MS. These multipliers are typically limited in their clock frequency and require a great deal of logic resources. Therefore a realization in, for example, freely programmable logic circuits, what are known as FPGA modules (FPGA=Field Programmable Gate Array) is difficult. These disadvantages become extremely noticeable, in particular with increasing precision requirements, i.e. with a greater bit width and a higher speed.

An additional significant disadvantage is that the fineness of the gradation of the variable modulation frequency MF depends on the width of the phase accumulator in the NCO. The precision of the sine and/or cosine vectors likewise depends on the bit width of the phase converter. Therefore the achievable clock rate of the NCO and the consumption of logic resources also increases dramatically for this with increasing demand for precision.

Therefore such a digital modulation with high clock frequencies and particularly high frequencies with regard to the radio-frequency signal have previously often been omitted, and instead analog mixing has been implemented.

A cost-effective usage of FPGAs has likewise been foregone, and alternatively items known as ASSPs (Application Specific Standard Products) have been used that provide a dedicated (i.e. not freely programmable) hardware and therefore normally must be produced specifically for the respective usage. Due to the special design for the individual usage purpose, however, such ASSPs are only economical in large quantities. Moreover, in such logic modules the phase accumulator of the NCO is also normally limited to 32 bits. Therefore in principle the same limitations as described above using FIG. 1 apply for such ASSPs.

### SUMMARY OF THE INVENTION

An object of the present invention is to provide a simple and cost-effective method and a corresponding circuit arrangement to generate a radio-frequency signal modulated depending on a low-frequency digital data stream, wherein the signal generation requires only relatively minimal logic resources even at high speeds and high frequencies.

In the method according to the invention, a clock signal is initially provided whose frequency is at least four times as high as the frequency of the radio-frequency signal to be generated. This clock signal is then used in order to mix the low-frequency data stream with an (advantageously particularly trivial) cyclical number series representing a continuous sine or cosine series. As will be explained below in detail, a mixing of the low-frequency data stream with a simple, cyclical number series is possible in a fast manner with very little logical effort. The single requirement is that the clock signal required to generate the number series has a correspondingly higher frequency than the desired radio-frequency signal must actually possess. However, this requirement can be satisfied without any problems.

A corresponding circuit arrangement requires: a data input to receive the low-frequency digital data stream; a clock signal generator to generate a clock signal whose frequency is at least four times as high as the frequency of the radio-frequency signal to be generated; a component group coupled with the clock signal generator and which is fashioned to mix (using the clock signal) the low-frequency data stream with a cyclical number series representing a continuous sine or cosine sequence; and an output to output the radio-frequency signal.

As is shown in the following, the component group that is required for the mixing of the low-frequency data stream with the cyclical number series can be of very simple design. Due to the low demand for logic resources, the circuit group can be particularly preferably implemented in a freely programmable logic circuit (FPGA) such that even specially tailored single circuit arrangements which are not produced in large volume can be produced cost-effectively.

A four-element number series is particularly preferably used as a cyclical number series in order to represent the sine or cosine series. In the most trivial case it thereby suggests itself to use a number series that consists of the elements “1”, “0”, “−1”, “0”. The two extreme values of a sine or, respectively, cosine series as well as the zero crossings are described simply with such a number series. This means that the entire sine or, respectively, cosine series will be described in the most trivial manner by four nodes.

Given use of such a cyclical number series with four elements, it is sufficient when the frequency of the clock signal is exactly four times as high as the frequency of the radio-frequency signal to be generated.

The component group for mixing the low-frequency data stream with a trivial number series representing a continuous sine or cosine series can possess a multiplexer for this in a particularly simple case, for example. The inputs of this multiplexer can then be respectively interconnected so that these represent the nodes of the sine or, respectively, cosine series. This means that the inputs are respectively populated with the digital data stream, wherein at every input the digital data stream is to be multiplied with a precisely defined factor (possibly also zero) which corresponds to an element of the specific number series, wherein the individual elements of the number series respectively form the nodes of the sine or cosine series to be represented.

For example, in the aforementioned preferred (because it is particularly trivial) cyclical number series with the elements “1”, “0”, “−1” and “0” the multiplexer possesses four inputs, wherein two of the inputs are charged with a constant input signal “0”, one of the inputs is charged with the low-frequency data stream itself and one input is charged with the inverted low-frequency data stream.

Using the clock signal, this multiplexer can then be controlled in a suitable manner so that the inputs are connected to an output of the multiplexer through corresponding to the sine or cosine series. For this the component group can advantageously comprise a counter which generates a number series “0”, “1”, “2”, “3”, “0”, “1”, “2”, “3” based on the clock signal of a simple. cyclically incremented number series. This counter is coupled with a control input of the multiplexer. The multiplexer is controlled on the basis of this cyclical number series so that—in a cyclical series—the input charged with the low-frequency data stream is connected first to an output of the multiplexer, then an input charged with zero, then the input charged with the inverted low-frequency data stream, and then again an input charged with zero. It is clear that the series can naturally begin at any of the inputs. It is only essential that a series is maintained so that a mixing of the low-frequency data stream actually ensues with a number series that represents a sine or cosine series. Naturally, a connection in the reverse order is also likewise possible, i.e. first to an input with the inverted low-frequency data stream, then to an input charged with zero, then to the input with the low-frequency data stream itself and then again to an input charged with zero. This ultimately corresponds only to a start of the series with the inverted input.

As mentioned, the component group is particularly preferably realized in a freely programmable logic circuit, i.e. in an FPGA module.

The circuit should advantageously be designed so that the clock signal is variably adjustable in order to be able to generate radio-frequency signals with different clock frequencies.

The use of a PLL circuit (PLL=phase locked loop; phase-coupled control loop) which allows a very precise generation of a variably adjustable but fixed radio-frequency signal as a clock signal generator suggests itself. Such PLL circuits are known to those skilled in the art and therefore need not be explained herein in detail.

The clock signal generator is advantageously installed as well in the freely programmable logic circuit. This primarily suggests itself given use of a PLL circuit. The clock signal generator itself can be triggered by an external fixed or variable reference signal, for example a system clock.

In particular given the design of a clock signal generator in an FPGA, the clock signal generator is designed so as to be dynamically reconfigurable for variation of the frequency of the clock signal. A variation of the frequency is thus possible even given a fixed reference signal, i.e. given a fixed system clock.

On the input side, the low-frequency digital data stream received by the circuit arrangement is advantageously initially supplied to a FIFO module (FIFO=“First In First Out”) which serves to buffer the low-frequency data stream and thus enables an adaptation to different clock frequencies. In particular the problem of a possible metastability given asynchronous clock transitions is therefore solved. Alternatively, a different circuit can also be used instead of such a FIFO module as long as it adapts the input data rate of the low-frequency data stream to the variable clock frequency and prevents metastability.

The output signal of the multiplexer already represents the desired radio-frequency output signal in digital form and can be converted into an analog radio-frequency signal. For this the output of the multiplexer merely needs to be coupled with a digital-analog converter. The digital-analog converter can thereby be triggered by the clock signal in a suitable manner.

Even given the circuit according to the invention, as in the conventional circuits the use of additional registers is possible in order to shorten the logic paths and thus to make the circuit as fast as possible. For example, such a register can also be interconnected directly at the output, i.e. after the multiplexer and before the digital-analog converter.

As explained above, such a generated radio-frequency signal can in particular be used as a magnetic resonance excitation signal in a magnetic resonance tomography system. A magnetic resonance tomography system that includes the previously described circuit arrangement in addition to all typical components known to those skilled in the art for generation of the magnetic resonance excitation signal is also encompassed by the invention.

Among other things, a scanner (magnetic resonance data acquisition unit) with a radio-frequency antenna arranged around a patient space, a magnet to generate a basic magnetic field and various gradient coils to generate magnetic field gradients are among the typical components of the magnetic resonance tomography system. Furthermore, a radio-frequency feed and a control device which suitably controls the magnetic field gradients and the radio-frequency feed, in particular for the low-frequency data stream, also belong among these typical components. Corresponding devices for data acquisition in order to detect and process the magnetic resonance signals with the aid of the antenna and/or special acquisition antennas and to reconstruct the magnetic resonance images from these also likewise belong to such a control device. However, all of these components are known to the man skilled in the art and therefore do not need to be explained in detail here. However, in the design of a magnetic resonance tomography system according to the invention the radio-frequency feed has the circuit arrangement according to the invention that is explained in detail herein.

### BRIEF DESCRIPTION OF THE DRAWINGS

FIG. 1 is a schematic block representation of a circuit arrangement to generate a radio-frequency signal modulated depending on a low-frequency digital data stream, according to the prior art.

FIG. 2 is a schematic block representation of a preferred exemplary embodiment of a circuit arrangement according to the invention.

FIG. 3 is a representation of the reference signal and the trivial number series generated from this within the circuit arrangement according to FIG. 2 to describe a continuous sine/cosine series.

FIG. 4 is a table to explain the mixing of the low-frequency digital data stream with the trivial number series to generate a digital radio-frequency signal in the circuit arrangement according to FIG. 2.

FIG. 5a is a graphical representation of the values of the low-frequency data stream and the trivial number series from the table in FIG. 4.

FIG. 5b is a graphical representation of the radio-frequency values from the table in FIG. 4.

### DESCRIPTION OF THE PREFERRED EMBODIMENTS

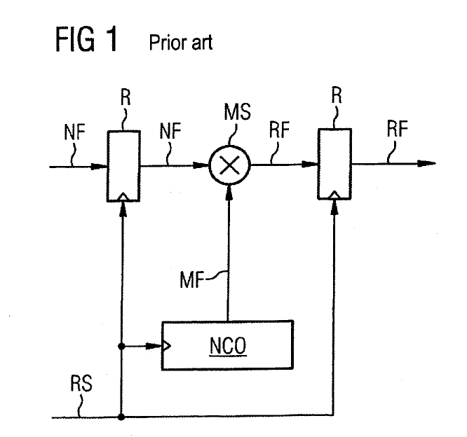

FIG. 1 was explained above in the introduction to describe the disadvantages of the previously used circuit arrangements for generation of radio-frequency signals modulated depending on a low-frequency digital data stream. In such a conventional circuit arrangement, the low-frequency digital data stream NF is digitally mixed with a mixing frequency MF (generated by an NCO in a mixing stage MS which requires relatively complicated logic resources) into the desired radio-frequency signal.

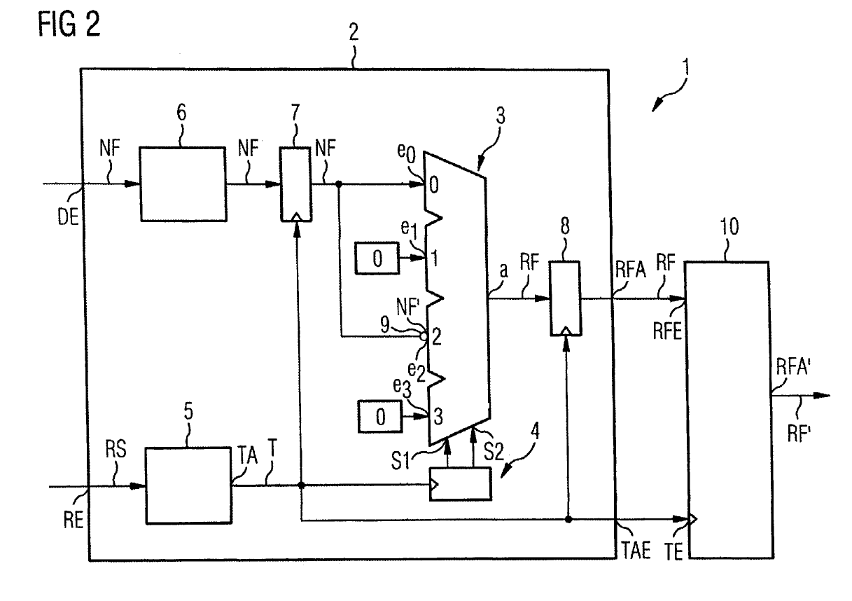

In contrast to this, FIG. 2 shows a particularly simple and therefore preferred design for realization of a circuit arrangement 1 according to the invention.

The core of this circuit arrangement 1 is a multiplexer 3 that has four inputs e₀, e₁, e₂, e₃ and two control inputs s₁, s₂ in a typical manner.

The low-frequency digital data stream NF is applied at a first input e₀. The logical value “0” is simply constantly applied at the second input e₁. An inverter 9 is arranged upstream of the third input e₂, to the input of which inverter 9 the low-frequency digital data stream NF is applied. Ultimately the inverted low-frequency data stream NF′ is thus applied at this input e₂. A fixed logical signal “0” is in turn applied at the fourth input e₃.

The control input of the multiplexer 3, which here consists in a typical manner of two logical (partial) control inputs s₁ and s₂ to which a logical signal “0” or “1” can respectively be connected, is connected with a counter 4. The input of this counter is in turn connected with the clock output TA of a PLL 5 which here serves as a clock generator 5.

This PLL is triggered by a reference signal RS, for example a system clock RS. This system clock RS can exhibit a frequency of 100 MHz, for example.

The operation of this circuit arrangement 1 is as follows:

The PLL 5 generates a clock signal T with quadruple the frequency of the actual desired radio-frequency signal RF. Since a radio-frequency signal RF for use as a magnetic resonance signal in an H₁ measurement in a 3 Tesla magnetic resonance tomograph must possess a carrier frequency of 123 MHz, a clock frequency of 492 MHz is consequently required for this.

The counter 4 then cyclically increments at this clock pulse and thus generates a cyclical series of values “0”, “1”, “2”, “3”, “0”, “1”, “2”, “3” . . . etc. This number series is provided in a binary-encoded form at the two inputs s₀, s₁ of the multiplexer 3.

Depending on the digital number respectively applied at the control input (or, respectively, the control inputs s₀, s₁), either the first input e₀, the second input e₁, the third input e₂ or the fourth input e₃ is connected to the output a of the multiplexer 3. This means that if the digital number “0” is present at the control input s₁, s₀ of the multiplexer 3, the low-frequency digital data stream NF is directly connected. If the number “1” is present, the logical “0” is connected. If the number “2” is present, the low-frequency digital data stream NF is connected in inverted form. Finally, if the number “3” is present, the logical “0” is connected again. The number 4 begins again with a “0” and the same sequence is repeated.

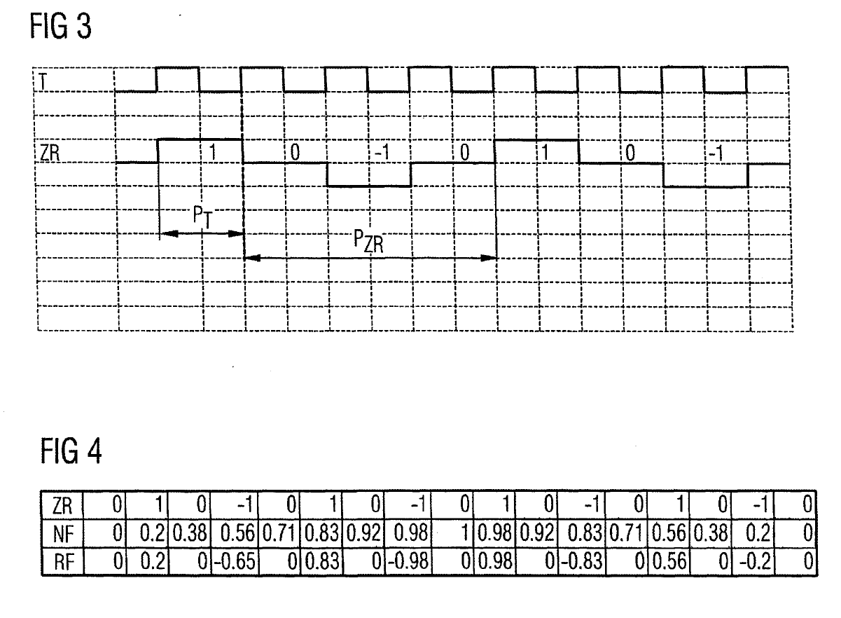

This procedure corresponds to an amplitude modulation of the digital data stream with a mixing frequency at the digital level which corresponds to one fourth of the clock frequency T. This can be seen from FIG. 3. There the clock signal T is plotted in the upper line, and the trivial number series “1”, “0”, “−1”, “0” (which describes a continuous sine or cosine series) generated in the multiplexer 3 on the basis of this clock signal is plotted below this. The frequency of this number series ZR is precisely one fourth of the clock frequency T; what is visible here is that the period P_{ZR} of the trivial number series ZR is precisely four times as long as the period P_{T} of the clock signal T. The trivial number series ZR thereby represents the sine and cosine vectors at 0°, 90°, 180° and 270°. This means that the sine or, respectively, cosine series is described with the aid of four simple nodes.

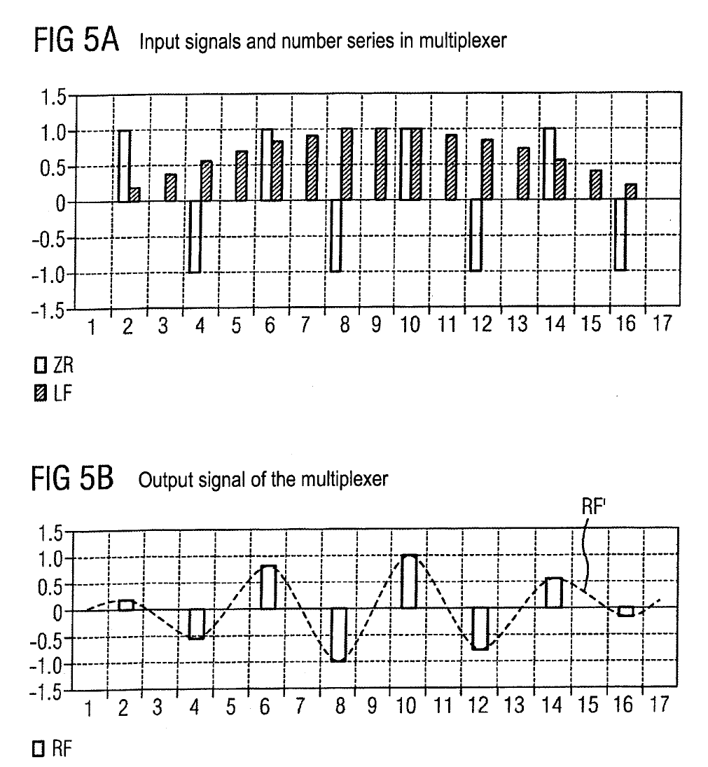

The operation of this simple mixing in the multiplexer 3 can be clarified again using FIGS. 4, 5a and 5b.

In the table in FIG. 4, the value of the trivial number series ZR is respectively shown in the uppermost row. The value of the low-frequency digital data stream NF that is present at the respective points in time is indicated in the second line. Both the value of the trivial number series ZR and the value of the low-frequency data stream NF are graphically plotted again in FIG. 5a. Finally, the signal present at the output a of the multiplexer, which ultimately yields a multiplication of the respective value in the first line with the value from the second line, is indicated in the third line of the table from FIG. 4. This is the already-modulated digital radio-frequency signal RF. These values are graphically plotted again in FIG. 5b. In a subsequent digital-analog converter the radio-frequency signal RF′ represented by the dashed line in FIG. 5b would result. This signal RF′ possesses the necessary carrier frequency at a level of one fourth of the frequency of the clock signal T and is amplitude-modulated according to the low-frequency data stream NF.

A complicated multiplier is not required for the mixing implemented in the manner previously described; rather, the shown inverter 9 and multiplexer 3 together with the simple counter 4 are sufficient.

Before the multiplexer 3, the low-frequency data stream NF is initially sent through a register 7. An additional register 7 is located after the output a of the multiplexer 3. These registers in turn serve to reduce the length of the combinatorial logic paths in order to achieve an optimally fast logic. The registers 7, 8 here are preferably likewise triggered by the clock signal T of the PLL 5.

As mentioned, the clock can be variably adjusted with the aid of the PLL 5. Therefore the low-frequency data stream is initially buffered at the input side in a typical FIFO module 6 in order to achieve an adaptation to different clock frequencies.

The radio-frequency signal RF is then provided to the radio-frequency input RFE of a digital-analog converter 10 that converts this into an analog radio-frequency signal RF′ and outputs it at its analog radio-frequency output RFA′. The triggering of this digital-analog converter 10 likewise ensues with the aid of the clock signal T of the PLL 5.

Apart from the digital-analog converter 10, all modules or, respectively, logic components of the circuit arrangement 1 are realized in an FPGA 2. This has a data input DE for the low-frequency data stream NF and a reference signal input RE to receive the system clock as a reference signal RS which is then relayed to the PLL 5. As outputs this FPGA 2 possesses: a radio-frequency output RFA to output the digital radio-frequency signal RF; and a clock signal output TAE to output the clock signal TA of the PLL 5 as a trigger signal for the clock input TE of the digital-analog converter 10.

The PLL 5 within the FPGA 2 is advantageously designed so as to be dynamically reconfigurable in order to be able to generate a clock signal T with variable frequency. In the event that only a fixed mixer frequency or carrier frequency is required for the radio-frequency signal RF, the PLL 5 can also be parameterized for a fixed output frequency. The externally supplied system clock (i.e. the reference signal RS) is likewise freely selectable in terms of its frequency (but normally is mono-frequent for an application).

As is apparent using the exemplary embodiment, the circuit arrangement according to the invention has multiple advantages. An FPGA can be used to generate the necessary radio-frequency, wherein the PLL that is present anyway in most FPGAs can be used for clock generation. A higher clock rate of the modulator can be achieved by omitting an NCO with a wide phase accumulator and wide sine or, respectively, cosine vectors that is otherwise typical in digital circuit arrangements. This is in particular necessary when particular radio-frequency signals should be generated. By the use of a clock signal T with variably adjustable frequency, radio-frequency signals with variable frequency can ultimately be generated without a wide logic (i.e. a logic operated with wide data words)—and therefore a correspondingly slow logic—being required for this.

The shown circuit arrangements are only exemplary embodiments that can be modified in the most varied manner by those skilled in the art without departing from the scope of the invention. The invention was described in an exemplary manner in the preceding using a magnetic resonance tomography system in the medical field, but invention can also be used in any other application fields or systems in which a modulated radio-frequency signal is required.

Although modifications and changes may be suggested by those skilled in the art, it is the intention of the inventors to embody within the patent warranted heron all changes and modifications as reasonably and properly come within the scope of their contribution to the art.

We claim as our invention:

1. Method to generate a radio-frequency signal modulated depending on a low-frequency digital data stream, comprising the steps of:
providing a clock signal at a frequency that is at least four times as high as the frequency of the radio-frequency signal to be generated; and
using said clock signal to mix the low-frequency data stream with a cyclical number series representing a continuous sine or cosine series.

2. Method according to claim 1, comprising using a four-element number series as said cyclical number series.

3. Method according to claim 2, comprising using a four-element number series consisting of “1”, “0”, “−1”, “0”.

4. Method according to claim 3, comprising controlling a multiplexer with four inputs using the clock signal by supplying two of the inputs with a constant input signal “0”, one input with the low-frequency data stream and one input with the inverted low-frequency data stream, and operating the multiplexer to connect the input supplied with the low-frequency data stream to an output of the multiplexer, then an input supplied with “0”, then an input supplied with the inverted low-frequency data stream, and then again an input supplied with “0”, in a cyclical sequence.

5. Method according to claim 4, comprising initially cyclically incrementing the number series based on the clock signal, and using the cyclical number series to control the multiplexer.

6. Method according to claim 1 comprising varying the clock signal.

7. Method according to claim 1 comprising generating the clock signal using a PLL circuit.

8. Method according to claim 1 comprising initially buffering the low-frequency data stream in a FIFO module.

9. Method according to claim 4 comprising converting the output of the multiplexer into an analog radio-frequency signal.

10. Method according to claim 9 comprising using the clock signal to control a digital/analog converter to convert the output of the multiplexer into said analog radio-frequency signal.

11. Method according to claim 1 comprising using the radio-frequency signal as a magnetic resonance excitation signal in a magnetic resonance tomography system.

12. Circuit arrangement to generate a radio-frequency signal modulated depending on a low-frequency digital data stream, comprising
a data input that receives the low-frequency digital data stream;
a clock signal generator that generates a clock signal at a frequency that is at least four times as high as the frequency of the radio-frequency signal to be generated;
a component group coupled with the clock signal generator that mixes the low-frequency data stream with a cyclical number series representing a continuous sine or cosine series using the clock signal;
an output at which the radio-frequency signal is emitted.

13. Circuit arrangement according to claim 12, wherein the module group comprises a multiplexer.

14. Circuit arrangement according to claim 13, wherein the multiplexer has four inputs, wherein two of the inputs are supplied with a constant input signal “0”, one input with the low-frequency data stream and one input with the inverted low-frequency data stream.

15. Circuit arrangement according to claim 14, the module group comprises a counter that generates a cyclical number series based on the clock signal;
said counter is coupled with a control input of the multiplexer to connect the multiplexer with the cyclical number series to connect the input supplied with the low-frequency data stream to an output of the multiplexer, then the input supplied with “0”, then the input supplied with the inverted low-frequency data stream, and then again the input supplied with “0”, in a cyclical sequence.

16. Circuit arrangement according to claim 12 comprising a FIFO module downstream of the data input that receives the low-frequency digital data stream.

17. Circuit arrangement according to claim 12 wherein the module group is formed by a freely programmable logic circuit.

18. Circuit arrangement according to claim 12 wherein the clock signal generator is a PLL circuit.

19. Circuit arrangement according to claims 17 wherein the clock signal generator is integrated as well into the freely programmable logic circuit.

20. Circuit arrangement according to claim 12 wherein the clock signal generator is controlled by a reference signal.

21. Circuit arrangement according to claim 12 wherein the clock signal generator is designed so that it can be dynamically reconfiqurable to vary the frequency of the clock signal.

22. Circuit arrangement according to claim 13 comprising a digital/analog converter downstream of an output of the multiplexer.

23. Circuit arrangement according to claim 22, wherein the clock signal generator has an output connected with a clock signal input of the digital/analog converter.

24. (canceled)

25. A magnetic resonance tomography system comprising:
a magnetic resonance data acquisition unit adapted to receive an examination subject therein to acquire magnetic resonance data from the examination subject, said magnetic resonance data acquisition unit comprising a radio frequency system supplied with a radio-frequency signal; and
a circuit arrangement that generates said radio frequency signal by modulation with a low-frequency digital data stream, said circuit arrangement comprising a data input that receives the low-frequency digital data stream, a clock signal generator that generates a clock signal at a frequency that is at least four times as high as the frequency of the radio-frequency signal to be generated, a component group coupled with the clock signal generator that mixes the low-frequency data stream with a cyclical number series representing a continuous sine or cosine series using the clock signal, an output which the radio-frequency signal is emitted.
